(19) United States
(12) Patent Application Publication
(10) Pub. No.: US 2005/0126618 A1
(43) Pub. Date: Jun. 16, 2005

(54) Device for producing electric energy

(76) Inventors: Bernhard Muller-Werth, Sulzbach (DE); Ewald von Puttkamer, Kaiserslautern (DE)

Correspondence Address: Friedrich Kueffner, Suite 910, 317 Madison Avenue, New York, NY, 10017, US

(21) Appl. No.: 10/938,398

(22) Filed: Sep. 11, 2004

(30) Foreign Application Priority Data
Sep. 15, 2003 (DE) 103 42 655.8

(51) Int. Cl. H01L 35/28

(52) U.S. Cl. 136/205; 136/212

(57) ABSTRACT

The invention concerns a device for producing electric energy with a bank that consists of a plurality of thermocouples, each of which has a first conductor element (19), a second conductor element (1; 2) connected with the first conductor element, and a third conductor element (20) connected with the second conductor element (1; 2) on a side opposite the first conductor element, wherein the conductive material of the first and third conductor elements (19, 20) is different from the conductive material of the second conductor elements (1; 2); the first conductor elements (19) are connected with a heat source (9), and the third conductor elements (20) are connected with a heat sink (11); and the first and third conductor elements (19, 20) of successive thermocouples alternately face each other in the bank. In accordance with the invention, the conductor elements that face each other in the bank are electrically connected with each other, and the second conductor elements alternately consist of a p-type (1) and an n-type (2) semiconductor.

The invention concerns a device for producing electric energy with a bank that consists of a plurality of thermocouples, each of which has a first conductor element, a second conductor element connected with the first conductor element, and a third conductor element connected with the second conductor element on a side opposite the first conductor element, wherein the conductive material of the first and third conductor elements is different from the conductive material of the second conductor elements; the first conductor elements are connected with a heat source, and the third conductor elements are connected with a heat sink; and the first and third conductor elements of successive thermocouples alternately face each other in the bank.

A thermoelectric battery of this type for converting heat to electric energy is described in DE 102 00 407 A1. The thermocouples of these thermoelectric batteries are connected in parallel.

The objective of the present invention is to improve the power capacity of a thermoelectric battery of this type.

In accordance with the invention, the device that achieves this objective is characterized by the fact that the conductor elements that face each other in the bank are electrically connected with each other, and the second conductor elements alternately consist of a p-type and an n-type semiconductor.

This thermoelectric battery of the invention, which uses series-connected thermocouples that have semiconductors, can deliver higher voltages than conventional batteries of the aforementioned type.

In an advantageous refinement of the invention, the first and the third conductor elements consist of foils or plates, and the semiconductors are each connected on opposite contact surfaces with the foils or plates, so that a stacked arrangement is formed, which consists of stacked foils or plates of this type.

The two facing first and third conductor elements can each be formed directly by a preferably single thermally conductive plate that is connected with the heat source or heat sink, or the foils or plates rest against a thermally conductive plate of this type on their sides that face away from the semiconductors.

Preferably, a plurality of n-type and p-type semiconductors is arranged between the foils or plates. This type of parallel connection of many thermocouples reduces the internal resistance of the thermoelectric battery and correspondingly increases the electric power.

The thermally conductive plates are preferably in contact with the heat source or heat sink by an edge that projects beyond the stacked arrangement, and it is advantageous for a layer that is both electrically and thermally insulating to be arranged between the stacked arrangement and the heat source or heat sink. This layer is penetrated by the plates, or the plates terminate in or on the layer.

A heat-transfer medium preferably flows inside the plates to achieve the most effective possible heat transfer by heat convection.

The heat source and heat sink each have a vessel, through which heat-transfer medium flows to supply or remove heat and into which, in one embodiment of the invention, the respective thermally conductive plates extend. The medium preferably flows through the vessel parallel to the surface of the thermally conductive plates. A portion of the thermally conductive plates that extends into the vessel is electrically insulated from the medium and the vessel. Alternatively, heat-conducting tubes could be wound around the projecting ends of the thermally conductive plates.

The use of heat pipes is a possibility for both the heat-conducting tubes and the thermally conductive plates.

The invention will now be explained in greater detail with reference to an embodiment illustrated in the accompanying drawings.

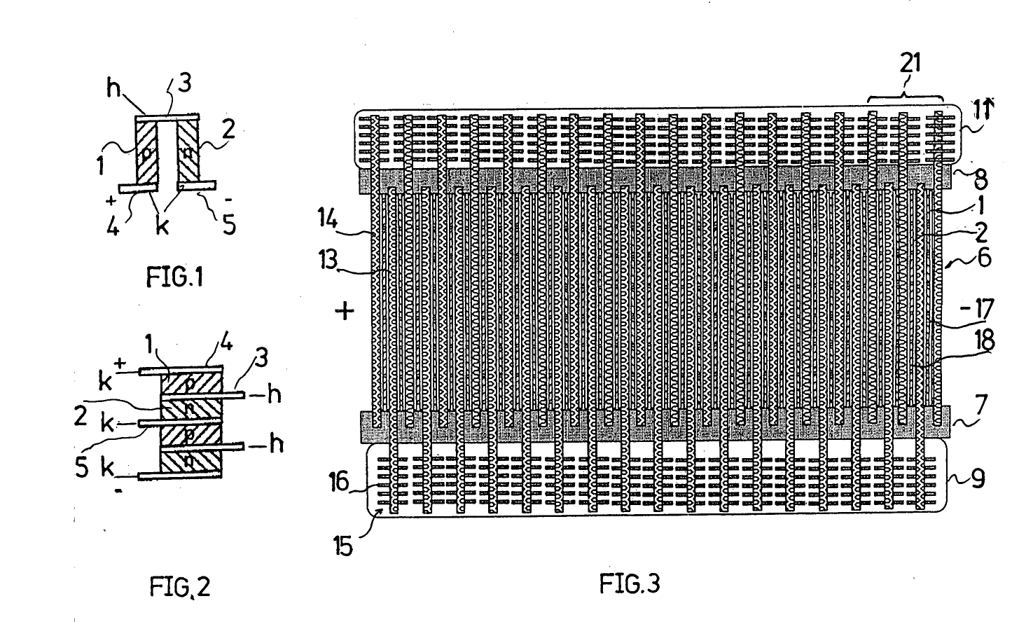

FIG. 1 shows a schematic representation of a thermoelectric elementary cell with a p-type and an n-type semiconductor, which is used in a thermoelectric battery in accordance with the invention.

FIG. 2 shows a series connection of elementary cells in accordance with FIG. 1.

FIG. 3 shows a thermoelectric battery in accordance with the invention, which uses the elementary cells shown in FIGS. 1 and 2.

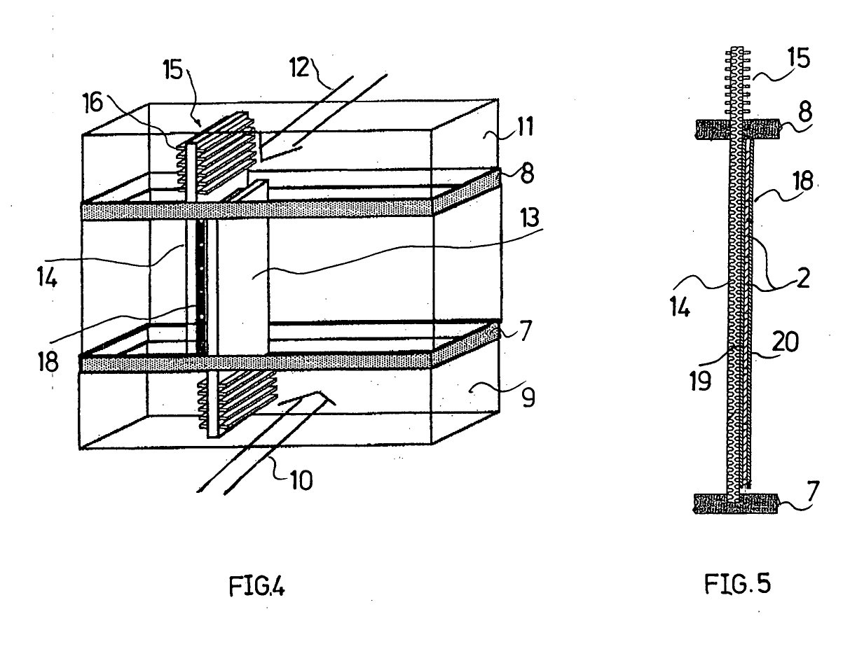

FIGS. 4 and 5 show partial views that explain the structure of the thermoelectric battery.

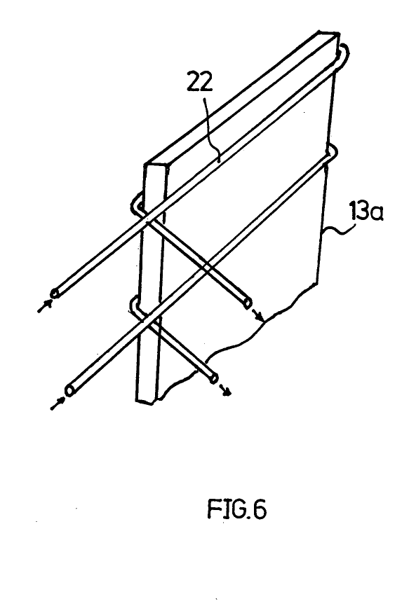

FIG. 6 shows another embodiment for connecting thermally conductive plates with a heat sink equipped with heat-conducting tubes.

According to FIG. 1, a p-doped semiconductor 1 is connected by a conductor element 3 with an n-doped semiconductor 2, and a conductor element 4 or 5 is located at the opposite ends of the semiconductors from the conductor element 3. If the conductor element 3 is at a higher temperature than the conductor elements 4 and 5, i.e., if hot contacts (h) are formed with the semiconductors by the conductor element 3, and cold contacts (k) are formed by the conductor elements 4 and 5, a thermoelectric voltage exists between the conductor elements 4 and 5 according to the temperature difference. In an elementary cell of the type shown in FIG. 1, the thermoelectric voltages of the two basic elements, which contain an n-doped or p-doped semiconductor, are cumulative.

According to FIG. 2, two elementary cells of this type are connected in series, wherein conductor element 5 forms a connecting piece to the second elementary cell, and conductor element 3 has contact surfaces with p-doped and n-doped semiconductors on opposite sides.

The arrangement shown in FIG. 2 corresponds to the basic structure of a thermoelectric battery shown in FIGS. 3 to 5.

As shown in FIG. 3, a stacked arrangement 6 formed from different plates is arranged between thermally and electrically insulating layers 7 and 8. The side of the insulating layer 7 that faces away from the stacked arrangement 6 is bounded by a vessel 9, through which a heat-supplying liquid flows, as indicated by arrow 10 (FIG. 4). This liquid has a temperature of, e.g., 130° C. The insulating layer 8 on the opposite side of the stacked arrangement 6 borders on a vessel 11, through which a heat-removing liquid flows, as indicated by arrow 12 (FIG. 4). This liquid has a temperature of, e.g., 80° C.

Thermally conductive plates 13 and 14, which are alternately connected with the vessel 9 and the vessel 11, are part of the stacked arrangement 6. They pass through the respective insulating layer 7 or 8 and terminate in the opposite insulating layer.

The thermally conductive plates 13, 14 supply or remove heat not merely by heat conduction but above all by heat convection, since a heat-transfer medium flows inside the plates.

A portion 15 of the thermally conductive plates 13, 14 that extends into the given vessel 9, 11 is electrically insulated from the medium that flows into the vessels 9, 11 parallel to the thermally conductive plates and has fins 16 to improve the heat transfer between the plates and the medium.

Layers 17 with p-type semiconductors 1 and layers 18 with n-type semiconductors 2 are alternately arranged between the thermally conductive plates 13, 14. Each of the layers 17, 18 has two copper foils 19 and 20 as first and third conductor elements, which enclose the semiconductors 1 or 2 as second conductor elements between them. The semiconductors 1 and 2, which are formed as thin plates, are distributed over the surface of the given layers 17, 18, e.g., in a square grid pattern. It is advantageous to prefabricate the layers 17, 18 to simplify the assembly of the thermoelectric battery.

In the embodiment in question, the insulating layers are 10 cm thick, the thermally conductive plates are 8 mm thick, the semiconductors 1, 2 are 1 mm thick, and the copper foils 19, 20 are 0.3 mm thick.

During the operation of the thermoelectric battery, heat-transfer medium flows through the vessels 9, 11, and the thermally conductive plates 13, 14 in thermal contact with the vessels take on different temperatures within the stacked arrangement. A thermally conductive plate 13 and a thermally conductive plate 14 with two layers 16 and one layer 17 form a unit 21 with a large number of thermocouples in parallel connection. A large number of such units are in turn connected in series in the stacked arrangement. A correspondingly multiplied thermoelectric voltage can be drawn off at the outer plates of the stacked arrangement.

FIG. 6 shows a thermally conductive plate 13a, whose end projecting from a stacked arrangement (not shown) is wound once with a bundle of heat-conducting tubes 22. For the sake of simplicity, only two of 25 tubes are shown. The tubes, which run parallel to one another, are connected to a heat vessel. The heat-conducting tubes 22 are preferably heat pipes.

1. Device for producing electric energy with a bank that consists of a plurality of thermocouples, each of which has a first conductor element (19), a second conductor element (1; 2) connected with the first conductor element, and a third conductor element (20) connected with the second conductor element (1; 2) on a side opposite the first conductor element (19), wherein the conductive material of the first and third conductor elements (19, 20) is different from the conductive material of the second conductor elements (1; 2); the first conductor elements (19) are connected with a heat source (9), and the third conductor elements (20) are connected with a heat sink (11); and the first and third conductor elements (19, 20) of successive thermocouples alternately face each other in the bank, wherein the conductor elements that face each other in the bank are electrically connected with each other, and the second conductor elements (1; 2) alternately consist of a p-type (1) and an n-type (2) semiconductor.

2. Device in accordance with claim 1, wherein the first and third conductor elements consist of foils (19, 20) and/or plates, the semiconductors (1, 2) are each connected to opposite contact surfaces with the foils (19, 20) and/or plates, and a stacked arrangement (6) of such foils (19, 20) or plates is formed.

3. Device in accordance with claim 2, wherein the facing first and third conductor elements are each formed directly by a preferably single thermally conductive plate that is connected with the heat source or heat sink, or that each of the foils (19, 20) or plates rests against a thermally conductive plate (13, 14) of this type.

4. Device in accordance with claim 3, wherein a plurality of n-type and p-type semiconductors (1, 2) is arranged between the foils (19, 20) or plates.

5. Device in accordance with claim 3, wherein the thermally conductive plates (13, 14) are in thermal contact with the heat source (9) or heat sink (11) by an edge that projects beyond the stacked arrangement (6).

6. Device in accordance with claim 5, wherein the medium flows parallel to the surface of the thermally conductive plates (13, 14).

7. Device in accordance with claim 3, wherein a heat-transfer medium flows through the thermally conductive plates (13, 14), possibly in the manner of heat pipes.

8. Device in accordance with claim 3, wherein the heat source (9) and heat sink each comprises a vessel (9, 11) for a medium that supplies or removes heat, and that the respective thermally conductive plates (13, 14) extend into the corresponding vessel.

9. Device in accordance with claim 7, wherein the portion (15) of the thermally conductive plate (13, 14) that extends into the vessel (9, 11) is electrically insulated from the medium.

10. Device in accordance with claim 6, wherein a thermally and electrically insulating layer (7, 8) is arranged between the stacked arrangement (6) and the vessels (9, 11).

11. Device in accordance with claim 1, wherein the heat source or heat sink comprises tubes (22) wound around the thermally conductive plates (13a).
